(19) United States
(12) Patent Application Publication
(10) Pub. No.: US 2026/0247864 A1
(43) Pub. Date: Aug. 20, 2026

(54) Piezoelectric microelectromechanical device and method of manufacture

(71) Applicant: Aalto University Foundation sr, Aalto (FI)

(72) Inventors: Kristina Bespalova, Aalto (FI); Elmeri Österlund, Aalto (FI); Mervi Paulasto-Kröckel, Aalto (FI); Glenn Ross, Aalto (FI)

(21) Appl. No.: 19/164,597

(22) PCT Filed: Sep. 20, 2023
(86) PCT No.: PCT/FI2023/050537

§ 371 Date: Sep. 12, 2025

(30) Foreign Application Priority Data
Mar. 23, 2023 (FI) 20237058

(51) Int. Cl. H10N 30/067; G01C 19/5621; G01C 19/5628; H10N 30/076; H10N 30/082; H10N 30/30; H10N 30/853; H10N 30/87

(52) U.S. Cl. CPC H10N 30/067; G01C 19/5621; G01C 19/5628; H10N 30/076; H10N 30/082; H10N 30/306; H10N 30/853; H10N 30/877

(57) ABSTRACT

According to an example aspect of the present invention, there is provided a method for manufacturing a microelectromechanical system, MEMS, device, comprising: forming at least one cantilever from a highly doped silicon layer on a buried oxide layer, the at least one cantilever having a first sidewall and a second sidewall, wherein the first and second sidewalls are perpendicular to the interface between the highly doped silicon layer and the buried oxide layer; growing a lead-free piezoelectric layer at least on the first sidewall and the second sidewall; and depositing electrically conductive material at least on the lead-free piezoelectric layer on the first sidewall and the second sidewall in order to form a first electrically conductive layer on the lead-free piezoelectric layer on the first sidewall and a second electrically conductive layer on the lead-free piezoelectric layer on the second sidewall.

### FIELD

This disclosure relates to the field of microelectromechanical systems (MEMS) and piezoelectric actuation.

### BACKGROUND

Devices based on piezoelectric actuation are some of the most promising among the microelectromechanical systems (MEMS). Emerging technology trends, such as the internet of things (IoT) or fifth-generation cellular network technology (5G), have led to increased attention to MEMS sensors and actuators. To meet the growing demand, MEMS devices should have improved characteristics, such as size, cost, reliability, and sensing output.

### SUMMARY

According to some aspects, there is provided the subject-matter of the independent claims. Some embodiments are defined in the dependent claims. The scope of protection sought for various embodiments of the invention is set out by the independent claims. The embodiments, examples and features, if any, described in this specification that do not fall under the scope of the independent claims are to be interpreted as examples useful for understanding various embodiments of the invention.

According to a first aspect of the present disclosure, there is provided a method for manufacturing a microelectromechanical system, MEMS, device, comprising forming at least one cantilever from a highly doped silicon layer on a buried oxide layer, the at least one cantilever having a first sidewall and a second sidewall, wherein the first and second sidewalls are perpendicular to the interface between the highly doped silicon layer and the buried oxide layer; growing a lead-free piezoelectric layer at least on the first sidewall and the second sidewall; and depositing electrically conductive material at least on the lead-free piezoelectric layer on the first sidewall and the second sidewall in order to form a first electrically conductive layer on the lead-free piezoelectric layer on the first sidewall and a second electrically conductive layer on the lead-free piezoelectric layer on the second sidewall.

According to a second aspect of the present disclosure, there is provided amicroelectromechanical system, MEMS, device, comprising at least one cantilever, the at least one cantilever forming part of a silicon layer comprising highly doped silicon, the at least one cantilever comprising a top surface, a bottom surface, a first sidewall and a second sidewall such that the first and second sidewalls connect the top surface to the bottom surface in a thickness direction of the silicon layer; a first lead-free piezoelectric layer on a first sidewall of the at least one cantilever; a second lead-free piezoelectric layer on a second sidewall of the at least one cantilever; a first electrically conductive layer on the first lead-free piezoelectric layer; and a second electrically conductive layer on the second lead-free piezoelectric layer.

### BRIEF DESCRIPTION OF THE DRAWINGS

FIG. 1 illustrates a microelectromechanical system comprising two cantilevers in accordance with at least some embodiments of the present invention;

FIG. 2A illustrates a microelectromechanical system comprising two cantilevers in accordance with at least some embodiments of the present invention;

FIG. 2B illustrates a side view of a microelectromechanical system comprising two cantilevers in accordance with at least some embodiments of the present invention;

FIG. 3A-3I illustrate a method for manufacturing of a microelectromechanical system comprising at least one cantilever in accordance with at least some embodiments of the present invention;

FIG. 3J illustrates an isometric view of a microelectromechanical system comprising at least one cantilever in accordance with at least some embodiments of the present invention;

FIG. 4 illustrates a scanning electron microscope (SEM) micrograph of a microelectromechanical system comprising a cantilever in accordance with at least some embodiments of the present invention;

FIG. 5 illustrates a schematic two spring-mass-damper systems of a MEMS vibratory gyroscope in accordance with at least some embodiments of the present invention;

FIG. 6. illustrates a piezoelectric thin film orientation of a cantilever in accordance with at least some embodiments of the present invention; and

FIG. 7. illustrates a two-dimensional view of the structure of microelectromechanical system comprising two cantilevers in accordance with at least some embodiments of the present invention.

### EMBODIMENTS

Microelectromechanical system (MEMS) devices are able to sense, control, and actuate on the microscale and generate effects on the macroscale. Next generation of microelectromechanical MEMS and nanoelectromechanical NEMS are needed in the applications such as low power wireless sensor networks for internet of things (IoT), optical 3D systems for object recognition, RF components in 5G/6G mobile communication networks, and smart catheters for minimum invasive systems-just to name a few. In these applications, the performance of the current MEMS devices needs to be improved, for example, regarding latency, accuracy, sensitivity, energy efficiency, fail-operational level reliability and miniaturization. New materials and advanced design concepts are required to fulfill the high expectations and the commercial potential miniaturized sensor and actuator systems currently encounter.

In the present disclosure, an in-plane actuation microelectromechanical system (MEMS) device and manufacturing method are disclosed. The MEMS device of the present disclosure comprises at least one cantilever. A cantilever is defined as a projecting beam that is supported at one end.

Piezoelectric MEMS provides lower power consumption, higher electromechanical coupling and better miniaturization potential compared with electrostatic transduction-based devices, but they are currently limited in design as piezoelectric films on planar surfaces enable primarily vertical motion. In the present disclosure, deposition of piezoelectric aluminum nitride, AlN, on vertical sidewalls of MEMS structures are presented, which enables more effective lateral actuation and sensing. Currently used line-of-sight physical vapor deposition, PVD, methods do not have adequate conformal coverage on vertical sidewalls. Here, high quality piezoelectric AlN process for vertical sidewalls of a MEMS feature by, for example, metalorganic chemical vapor deposition, MOCVD, is disclosed. Further, atomic layer deposition, ALD, may be used to yield highly conformal layers on sidewalls even for electrically conductive materials.

If deflection and vertical directions are controlled, such effects can be combined to generate high-precision three-dimensional (3D) displacements in a single integrated device structure. This enables higher integration and miniaturization of 3D MEMS actuators, sensing rotations along all three axes and tunable nanophotonic components.

Piezoelectric materials can experience deformation under applied electric field, or conversely, the deformation of a piezoelectric material induces an electric field. In the present disclosure, the lateral electromechanical transducer utilizes the piezoelectric properties of a lead-free piezoelectric materials, such as aluminium nitride, AlN. For conventional piezoelectrically driven cantilevers, piezoelectric layer is grown on a planar surface of a wafer, manufactured for example from silicon, Si. When a voltage is applied between two electrodes intermediated by a piezoelectric material comprised in a cantilever, the cantilever is deflected along a plane passing through the two electrodes and the piezoelectric material, in other words, perpendicular to the planar surface of the wafer wherein the piezoelectric layer is grown. For lateral motion, piezoelectric layer and two electrodes are grown on opposite sidewalls of a silicon cantilever. When voltage is applied to the electrodes of such structure, the cantilever moves laterally, perpendicular with respect to the orientation of the sidewalls.

The disclosed lateral electromechanical transducer is a cantilever structure with an aluminium nitride, AlN, layer on the sidewalls of a highly doped silicon beam. Aluminium nitride, AlN, may be deposited on the sidewalls using metalorganic chemical vapor deposition (MOCVD). The highly doped silicon beam acts as a proof mass and at the same time for piezoelectric actuation as a reference electrode, sometimes termed a bottom electrode (BE). In the current disclosure, bottom electrode, BE, and reference electrode are used interchangeably. Another electrode, sometimes termed as a top electrode (TE) resides such that piezoelectric material is between the bottom electrode and the top electrode. The top electrode may comprise, for example, molybdenum, Mo, titanium nitride, TiN, or aluminium, Al. The electrode may be deposited, for example, using atomic layer deposition, ALD. In-plane motion of the cantilever is enabled when a voltage is applied between the top electrode, TE, and the bottom electrode, BE, thereby contributing to the deformation, of the piezoelectric layer, and deflection of the cantilever. Deflection of the cantilever depends on the geometry of the cantilever and thickness of piezoelectric layer. For fabrication of one-end clamped beam, in other words, a type of a cantilever, silicon on insulator (SOI) wafers may be used.

In accordance with the present disclosure, there is provided a method for manufacturing a microelectromechanical system, MEMS, device, comprising:
forming at least one cantilever from a highly doped silicon layer on a buried oxide layer, the at least one cantilever having a first sidewall and a second sidewall, wherein the first and second sidewalls are perpendicular to the interface between the highly doped silicon layer and the buried oxide layer;
growing a lead-free piezoelectric layer at least on the first sidewall and the second sidewall; and
depositing electrically conductive material at least on the lead-free piezoelectric layer on the first sidewall and the second sidewall in order to form a first electrically conductive layer on the lead-free piezoelectric layer on the first sidewall and a second electrically conductive layer on the lead-free piezoelectric layer on the second sidewall.

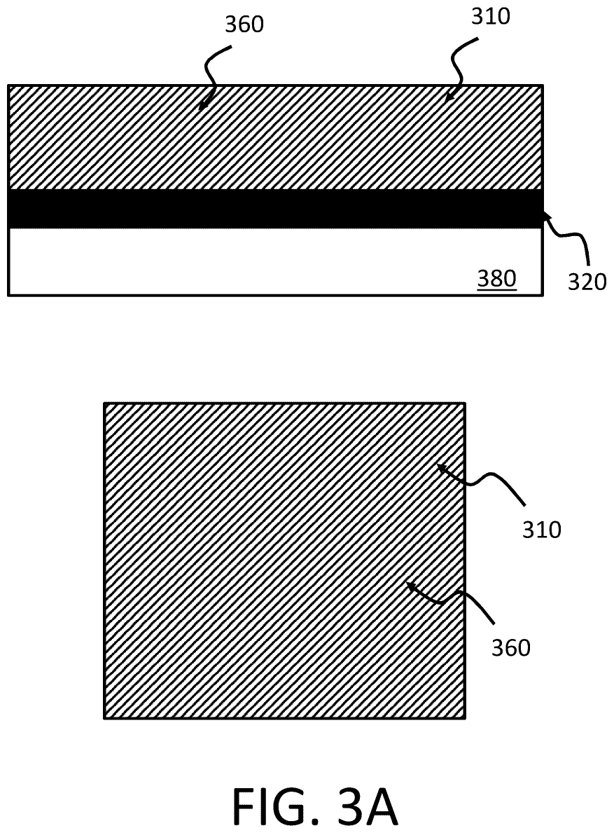

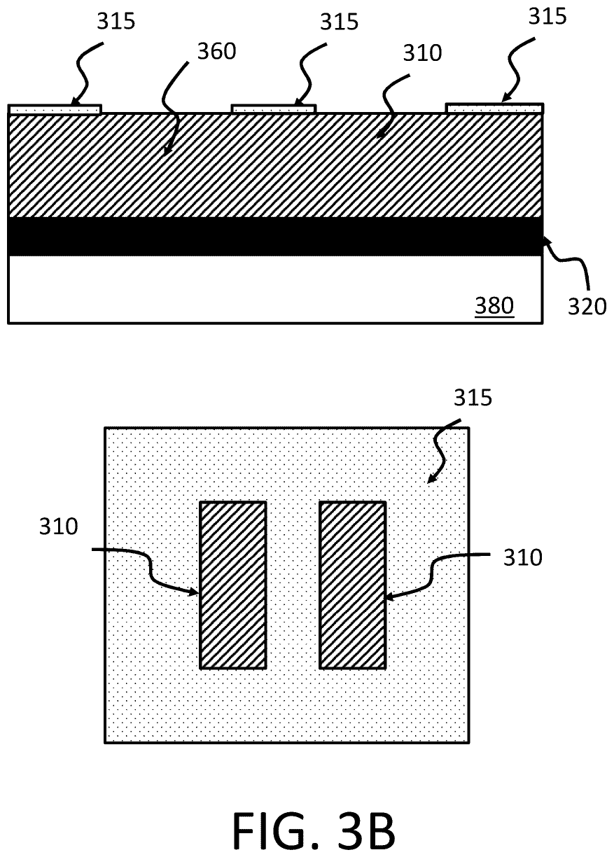

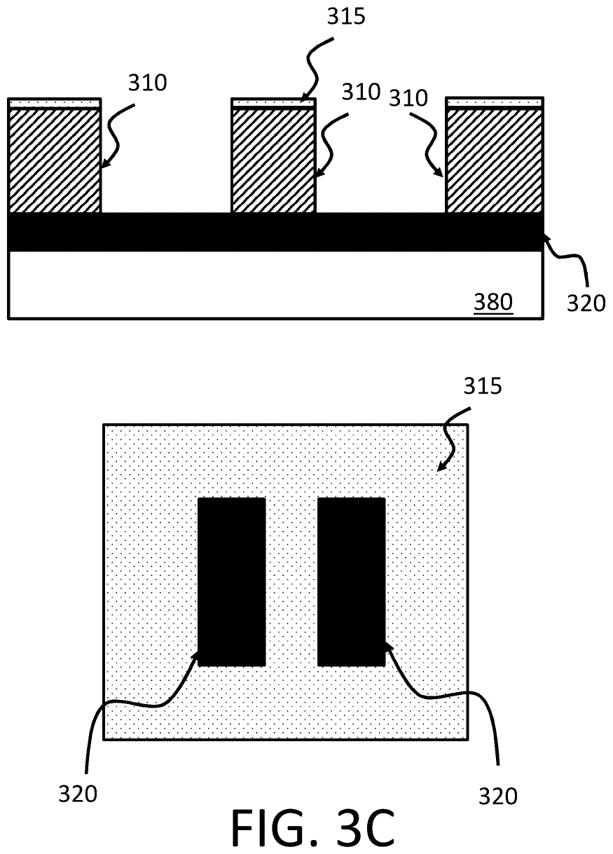

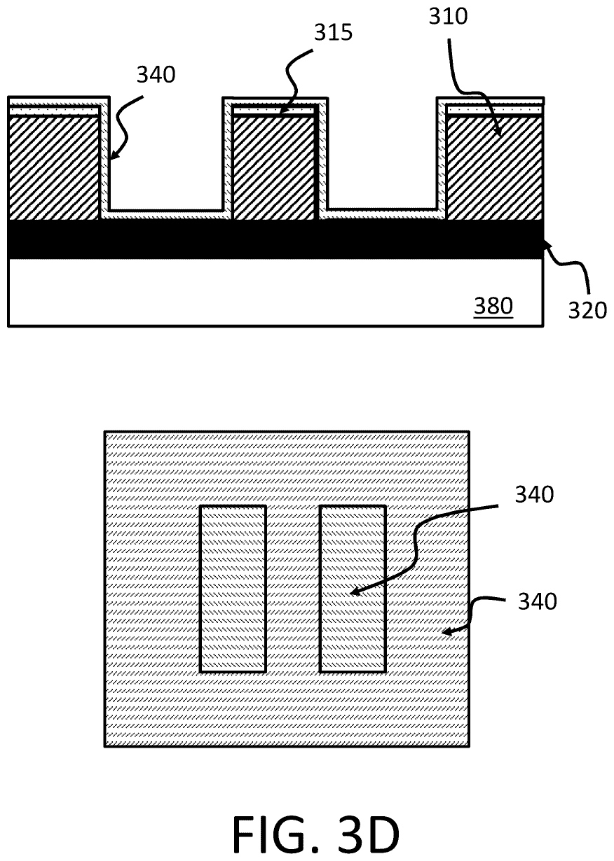

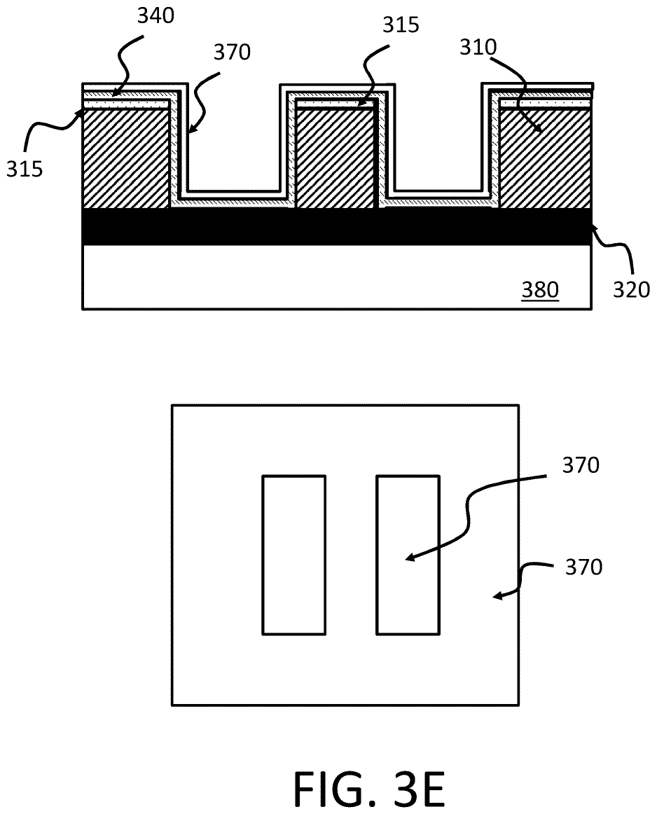

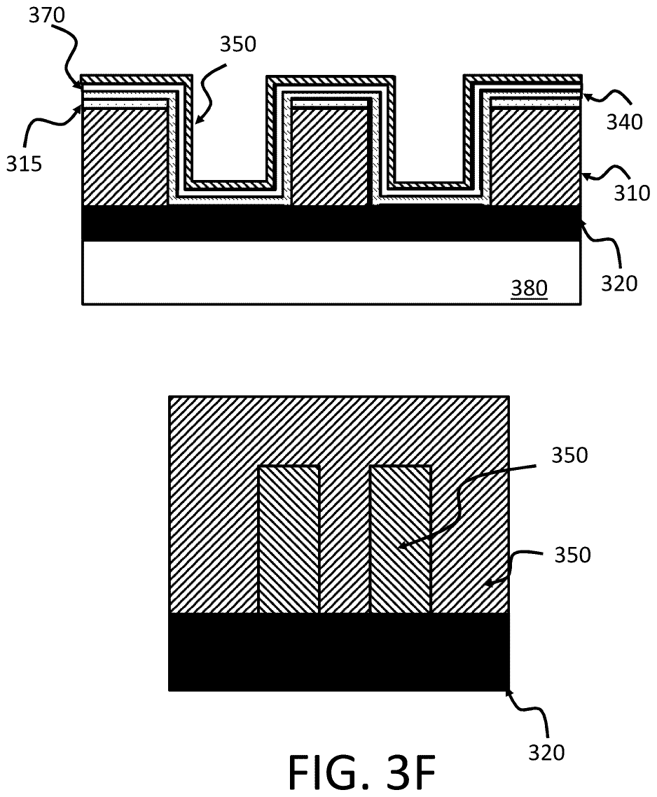

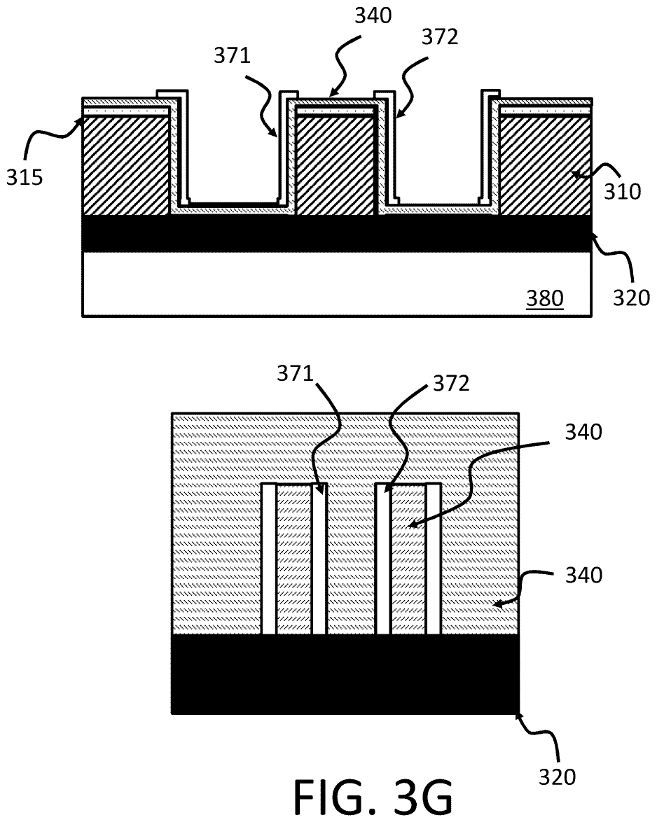

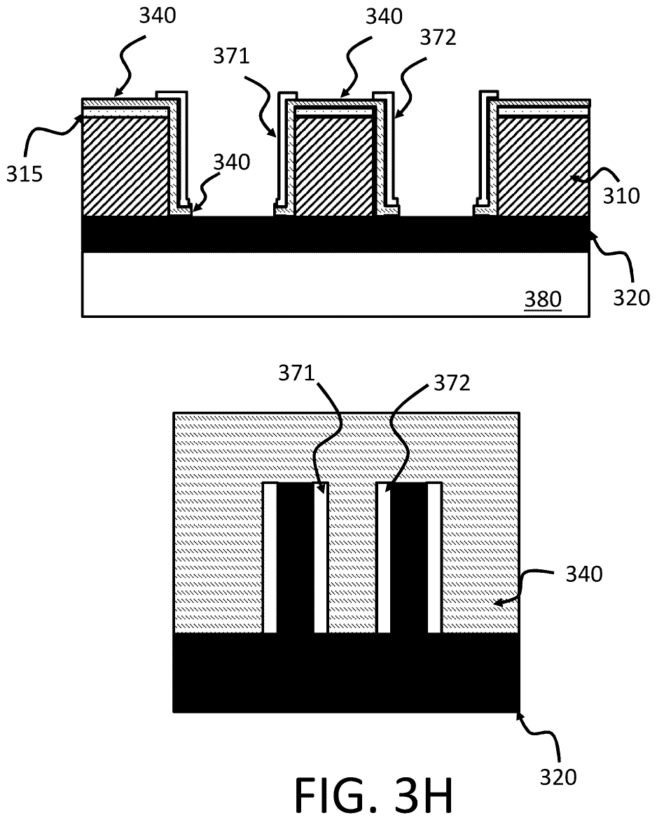

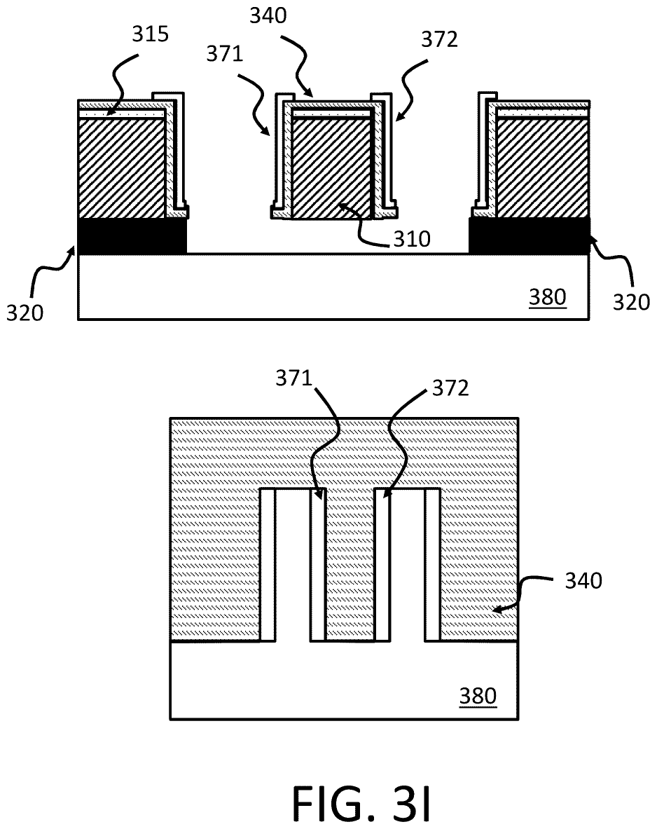

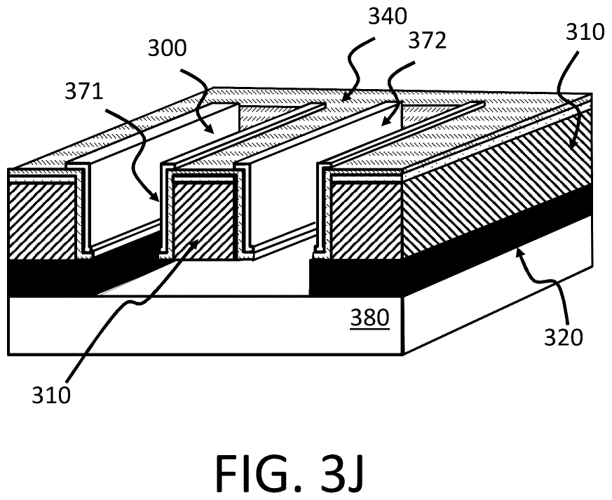

FIG. 3A to FIG. 3I illustrate a method for manufacturing a cantilever in accordance with at least some embodiments of the present invention. In FIG. 3A, a silicon on insulator is obtained comprising a device layer 360, buried oxide layer 320 and a base material 380. The device layer comprises highly doped silicon 310. In FIG. 3B, an insulator mask 315, preferably thermal silicon dioxide, SiO2, is applied to obtain a mask for the device layer. In FIG. 3C, the device layer 360 has been in part etched through to the buried oxide layer 320. Additionally, the insulator mask 315 may be removed after the device layer has been etched in part. In FIG. 3D, a lead-free piezoelectric layer 340 is deposited on the device layer 360, the buried oxide layer 320, and optionally the insulator mask 315. Depositing may be done using metalorganic chemical vapor deposition, MOCVD. In FIG. 3E, electrically conductive layer 370 is deposited. Depositing may be done with atomic layer deposition, ALD. In FIG. 3F, insulator 350, for example aluminium oxide, Al₂O₃, is deposited on the electrically conductive layer 370. Depositing may be done with atomic layer deposition, ALD. In the final product, one end of the cantilever is connected to the device layer 360. The opposite end may be separated from the device layer 360 by etching through the relevant part of the device layer 360 down to the buried oxide layer 320. In FIG. 3G, the electrically conductive layer 370 is patterned to obtain a pattern extending over at least in part the sidewalls of the cantilever. In FIG. 3H, the lead-free piezoelectric layer 340 is patterned. In FIG. 3I, the buried oxide layer 320 is etched, thus, releasing a cantilever structure, with sidewalls comprising a piezoelectric layer 340 and electrically conductive layer 371, 372. The etching may be done using hydrofluoric acid (HF) or using vapor phase etching, VPE. FIG. 3J illustrates the formed cantilever 300, wherein the cantilever 300 comprises highly doped silicon 310, a lead-free piezoelectric layer 340, first electrically conductive layer 371 and a second electrically conductive layer 372, and said cantilever 300 is attached to and supported by the device layer 360 on one end.

In a preferred embodiment, the lead-free piezoelectric material comprises aluminium nitride, AlN. The electrically conductive layer may comprise titanium nitride, TiN. The electrically conductive layer may comprise aluminium, Al. The electrically conductive layer may comprise molybdenum, Mo.

In the present disclosure, highly doped silicon layer is characterized as doped silicon with a resistivity of less than 0.01 Ω·cm, preferably with a resistivity of less than 0.005 Ω·cm.

In an embodiment, the highly doped silicon is comprised in a device layer of a silicon-on-insulator (SOI) substrate. Such a silicon-on-insulator (SOI) substrate comprises of said device layer 360 and a buried oxide layer, BOX 320. Such a buried oxide layer 320 may comprise of silicon dioxide SiO₂, for example. Further, the silicon-on-insulator (SOI) may comprise a base material layer 380, from which the device layer 360 is separated by the buried oxide, BOX, layer 320. Such a base material layer 380 may be, for example, silicon.

In an embodiment, forming of the at least one cantilever is accomplished by etching an at least one cavity on the device layer using, for example, a lithography process after which at least one of wet etching and dry etching is conducted. The at least one cavity forms a first sidewall and a second sidewall of the at least one cantilever. Example of wet etching comprises etching using potassium hydroxide, KOH. Another example of wet etching comprises etching using tetramethylammonium hydroxide, TMAH. Example of dry etching is inductively coupled plasma reactive ion etching using a sulfur hexafluoride oxygen mixture, SF6/O2. Further, silicon dioxide, SiO₂, may be used as a mask for etching the at least one cavity. In such cases, the silicon dioxide may also be used as isolation between aluminium nitride, AlN, and a reference electrode comprising highly doped silicon. The silicon dioxide acting as a mask assists in the prevention of out-of-plane deflection of the at least one cantilever.

A piezoelectric material is grown on the sidewalls of the at least one cantilever. Growing may comprise metalorganic chemical vapor deposition, MOCVD. Example of a lead-free piezoelectric material is aluminium nitride, AlN. Further electrically conductive layer is deposited at least partly on the lead-free piezoelectric material. Examples of an electrically conductive layer are titanium nitride, TiN, aluminium, Al and molybdenum, Mo. In some embodiments, an isolating layer is deposited. An example of an insulator layer comprises aluminum oxide, Al₂O₃. The insulator layer, comprising, for example Al₂O₃, may act as a hard mask for etching areas that connect two or more antiparallel cantilevers, or so-called silicon-bridge, Si-bridge. Alternatively the hard mask may define an end portion of a single cantilever. The so-called silicon-bridge assists in forming the cantilever, as the unmasked end of a cantilever is separated from surrounding device layer structure.

Forming of the at least one cantilever may be partly separated from surrounding device layer and separated from the buried oxide layer, BOX by etching. The buried oxide layer, BOX surrounding the at least one cantilever may be etched with hydrofluoric acid (HF), or using vapor phase etching, VPE, thus, forming the at least one cantilever. Hydrofluoric acid, HF has minimal to no effect on layers comprising AlN and TiN as these materials are stable in HF, and thus, no additional protection is needed.

The present disclosure overcomes some of the limitations and drawbacks of currently available microelectromechanical systems, MEMS. Specifically, the current disclosure addresses shortfalls in current electrostatic and piezoelectric MEMS transduction. Examples of the advantages in accordance of the present disclosure are the electromechanical coupling of lateral motion, integration of full 3D-motion in a single MEMS element, high-scalability, and vertical MEMS element arrays. In current inertial MEMS solution, complex multi-modal resonating elements are required for sensing of forces in orthogonal directions. The embodiments of the current disclosure overcome the need for complex design by having a fully 3D-electromechanical coupling in a single MEMS element. Full 3D motion of an element may be realized by having the lateral piezoelectric transduction integrated with horizontal transduction. Integrating piezoelectric MEMS elements vertically enables high lateral functional density, beneficial for MEMS scalability. Finally, vertical MEMS arrays with high lateral function density enables increased electromechanical coupling sensitivity, beneficial for highly sensitive sensors of low energy scavenging techniques.

In an embodiment, at least two parallel cantilevers are formed and separated by a gap, the gap being less than 200 μm, wherein parallel describes the orientation of the silicon beams and released cantilevers. In another embodiment, the gap may be between 50 μm and 300 μm. Such a microelectromechanical system may be used, for example, as gyroscope with drive and sense electrodes on both cantilevers. More than two cantilevers may be in such a configuration. Further, in some embodiments, a cantilever may be antiparallel or perpendicular with respect to another cantilever. In some embodiments, more than two cantilevers may be formed.

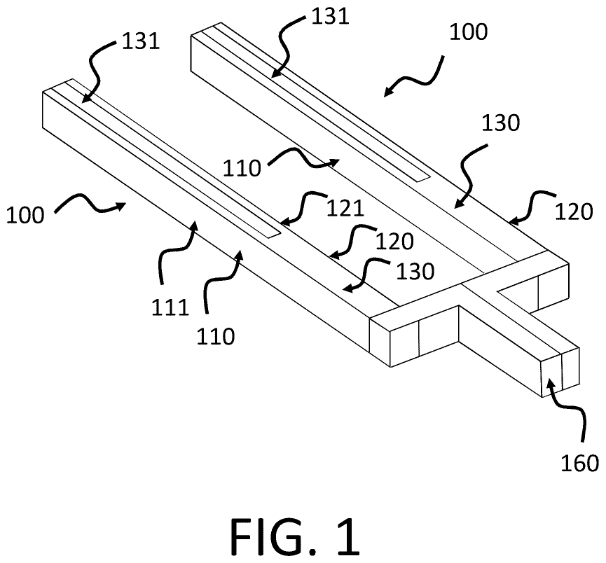

Here, a MEMS device and method comprising lead-free piezoelectric material is described. FIG. 1 illustrates a microelectromechanical system (MEMS) device in accordance with at least some embodiments of the present disclosure. A cantilever comprises highly doped silicon, lead-free piezoelectric material on surface of the highly doped silicon, and an electrically conductive layer on the surface of the lead-free piezoelectric material. The highly doped silicon acts as a reference electrode. In accordance of the present disclosure, there is provided a microelectromechanical system (MEMS) device, wherein at least one cantilever comprises highly doped silicon as a reference electrode, a first sidewall, a first lead-free piezoelectric layer on the first sidewall, a first electrode on the first piezoelectric layer, a second sidewall, a second lead-free piezoelectric layer on the second sidewall and a second electrode on the second lead-free piezoelectric layer. The first and the second lead-free piezoelectric layer may comprise, for example, aluminium nitride, AlN.

According to some embodiments, two cantilevers may be incorporated to obtain a tuning fork structure. Hereon, the properties of such a two cantilever MEMS system are described.

The actuation mechanism of the MEMS device could be generated by a wide variety of methods. Sensor's design includes thermal, electromagnetic, and electrostatic transduction. Among these methods, piezoelectric actuation demonstrates significant advantages, mainly due to its high electromechanical coupling. This results in lower power consumption in piezoelectric devices, while electrostatically actuated sensors require an additional charge pump to increase their input voltage amplitude. Currently, some of the most widespread piezoelectric materials in existing MEMS devices are aluminum nitride (AlN) and lead zirconate titanate (PZT). AlN is an environmentally friendly material with the availability to be compatible with the metal-oxide-semiconductor (CMOS) processes, which PZT does not have. These facts made AlN more promising in the design of vibration-based MEMS sensors.

Commonly, commercial inertial sensors are electrostatically actuated, while their sense output is measured by the capacitance change in sense direction. However, recent studies show a significant range of published designs based on piezoelectric material properties. For instance, MEMS piezoelectric solid disk gyroscope was designed with an elliptic bulk acoustic wave mode. Another piezo-based MEMS gyroscope utilizes a beam-based structure, where a piezoelectric layer is sandwiched between two electrodes.

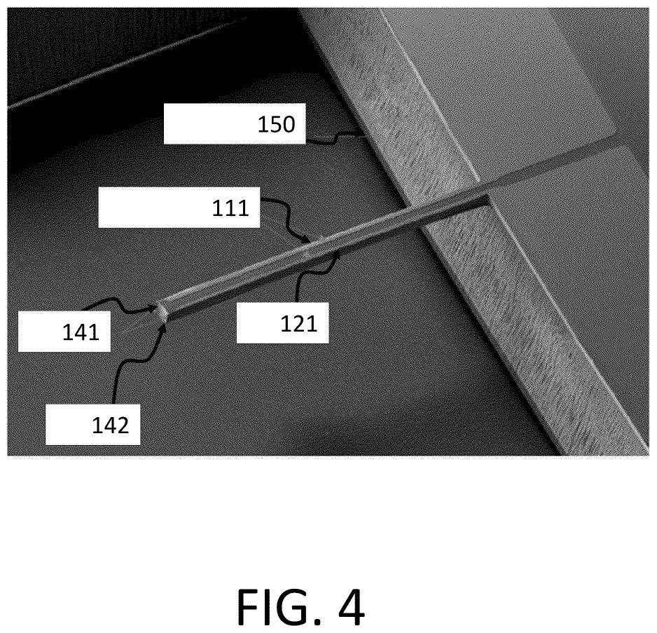

Among AlN-based piezoelectric devices, the most common approach to utilize out-of-plane deflections by the sputtering deposition of AlN on a substrate. However, multi-axis sensors, such as gyroscopes, require perpendicular drive and sense directions, what creates a high demand for in-plane actuation. Moreover, enhanced in-plane actuation and sensing can also find their application beyond inertial sensors. Energy harvesters based on AlN could generate power by harvesting small magnitudes of energy from ambient vibrations. Implementation of the AlN sidewall structure will allow to generate voltage from in-plane deflections and lead to the increased device's output. In addition, in-plane motion creates the opportunity to stack energy harvesters into a united array, which will multiply overall harvesting efficiency. At the same time, piezoelectric in-plane actuation could be attractive in high quality switching of RF MEMS. The challenge with in-plane actuation and sensing is the deposition of the piezoelectric and electrode materials on the vertical sidewalls with high crystal quality. To overcome this, deposition has been achieved by metalorganic chemical vapor deposition (MOCVD) or atomic layer deposition (ALD) of the piezoelectric AlN and metal electrodes. FIG. 4 shows the SEM picture of the in-plane cantilever with the MOCVD deposited piezoelectric AlN sidewalls fabricated on a silicon-on-insulator (SOI) wafer. The main feature of this structure is the opportunity to utilize bimorph design by means of piezoelectric thin films on both sides of the cantilever. The voltage is applied over the AlN thin film sidewalls by contacts through the metal electrode's area for actuation. Following that, the proposed sidewall structure utilizes the increased area of metal electrodes, which even more improves the observable sensor's output.

In the current work, to fully understand the operating characteristics and the perspective of the MEMS design with vertical piezoelectric AlN thin-film structures, a comprehensive FEM study was undertaken. Multiphysics study allows the implementation of the properties of the anisotropic and piezoelectric materials and their coupling with the FEM software packages. To demonstrate the potential of the sidewall concept in an inertial sensing application, a COMSOL FEM simulation of the half-fork Coriolis vibrating gyroscope (CVG) with the piezoelectric AlN sidewall's structure was performed.

The proposed device's main characteristics, such as mechanical rate sensitivity and scaling, were calculated after simulations to estimate overall gyroscope performance. A significant amount of commercial and research-based MEMS gyroscopes allows for comparing the output of the modeled gyroscope presented in this work with the existing devices.

Geometry optimization was undertaken to investigate the potential performance of a sidewall-piezoelectric structure in MEMS. Multi-parameter characterization was performed in COMSOL to obtain the mechanical sensitivity for a range of the modified design options. Since the bimorph piezoelectric cantilever is the fundamental structure of the proposed MEMS gyroscope device, initial geometry parameters were assumed by considering fabricated samples of the released cantilever, shown in FIG. 4.

MEMS vibrating gyroscope working principle is based on the Coriolis acceleration effect. When the movable proof mass is in resonance with the applied angular velocity, the Coriolis force generates the displacement in the direction perpendicular to the linear velocity.

A basic single-axis Coriolis vibrating gyroscope (CVG) could be described as a two-DOF resonator. It consists of two mass-spring-damper systems that are expressed by the equations of motion for both drive and sense axes:

$${m}_{d} \ddot{x} + {r}_{d} \dot{x} + {k}_{d} \dot{x} = {F}_{d} sin ( ω t )$$

$${m}_{s} \ddot{y} + {r}_{s} \dot{y} + {k}_{s} y = {F}_{c o r}$$

where for drive direction: md is the mass, r_{d}—damping coefficient, k_{d} stiffness, and F_{d} sin(ωt) is the applied force, while for sense: mₛ, rₛ, kₛ, F_{cor} are the mass, damping coefficient, stiffness, and the Coriolis force applied in sense direction, respectively.

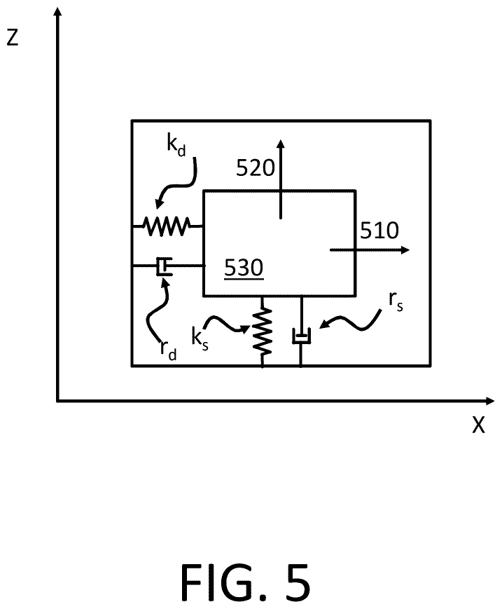

Coriolis force amplitude is expressed as follows:

$${F}_{c o r} = - 2 m ( {v}_{d} \times {Ω}_{ext} )$$

where m is the mass of the moving system, v_{d}—is the linear velocity and Ωₑₓₜ is the angular velocity. The lumped gyroscope system is illustrated in FIG. 5.

Components of motion from the equations of motion for both drive and sense axes could be contributed to the COMSOL FEA modeling as follows:
m_{d}, mₛ—the mass of the built geometry, material density
r_{d}, rₛ—presented in the model as a Rayleigh damping, values are based on Q-factor and resonant frequency (will be discussed in more detail in Section 3.3)
k_{d}, kₛ—stiffness for drive and sense modes corresponds to anisotropic properties of used materials (e,q, elastic, and compliance matrices) and physical constraints (fixed plane constraint)

The proposed design fully utilizes the piezo-cantilever structure. AlN vertical sidewalls are responsible for driving direction, causing in-plane motion of the cantilever. Piezoelectric thin films deform under applied external voltage, creating cantilever deflections with linear velocity in the drive direction. The sense direction is opposite to drive, and one can achieve it by having out-of-the-plane motion on the same cantilever. Therefore, an angular velocity must be applied to observe deflections in the sense direction. Eventually, sense piezoelectric thin film located on the top of the cantilever transforms mechanical deformation caused by Coriolis force into the output voltage.

FIG. 1 depicts a schematic view of the half-tuning fork CVG based on manufactured AlN piezoelectric cantilevers shown in FIG. 4. The gyroscope of 160 μm in width and 420 μm in length with an overall thickness of 50 μm is made of 0.04 Ohm p-type silicon, which is also defined as a ground electrode. The mechanical structure of the resonator consists of two cantilevers connected between each other and with the deposited AlN layers. In addition, the following boundary conditions were applied to simulate the gyroscope rotation: a rotating frame around the Y-axis with a specified value of angular velocity νa and a fixed constraint at the uniform end of the sensor's Z-X plane.

To solve the FEA model that contains the anisotropic properties, it is required to determine the elastic constants. Experimentally obtained elastic-stiffness coefficients of the AlN wurtzite-type-structure are expressed with the following stiffness tensor:

$$[ \begin{matrix}{C}_{11} & {C}_{12} & {C}_{13} & & & \\ {C}_{21} & {C}_{22} & {C}_{23} & & & \\ {C}_{31} & {C}_{32} & {C}_{33} & & & \\ & & & {C}_{44} & & \\ & & & & {C}_{44} & \\ & & & & & \frac{1}{2} ( {C}_{11} - {C}_{12} )\end{matrix} ] = [ \begin{matrix}410 & 149 & 99 & & & \\ 149 & 410 & 149 & & & \\ 99 & 149 & 389 & & & \\ & & & 125 & & \\ & & & & 125 & \\ & & & & & 130.5\end{matrix} ]$$

In addition, the corresponding stress-piezoelectric constant tensors were utilized to define modeled material as a piezoelectric.

$$[ \begin{matrix} & & & & {e}_{24} \\ & & & {e}_{24} & \\ {e}_{31} & {e}_{31} & {e}_{33} & & \end{matrix} ] = [ \begin{matrix} & & & & - 0.48 \\ & & & - 0.48 & \\ - 0.58 & - 0.58 & 1.55 & & \end{matrix} ] [ \frac{C}{{m}^{2}} ]$$

In the proposed modeling, Al electrodes are located on each side of the cantilevers in order to simulate piezoelectric actuation. Two cantilevers oscillate in a counter-phase with the applied AC voltage on each drive electrode.

When the gyroscope oscillates at resonance along the X-axis, the rotating frame around Y-axis causes the displacement in the Z-axis direction from the Coriolis force. There are two Al electrodes on each cantilever to sense generated electrical signals from the deformed piezoelectric layer. Out-of-the-plane deflections have opposite directions. Thus, the difference in voltage between the two electrodes serves as an absolute sense output.

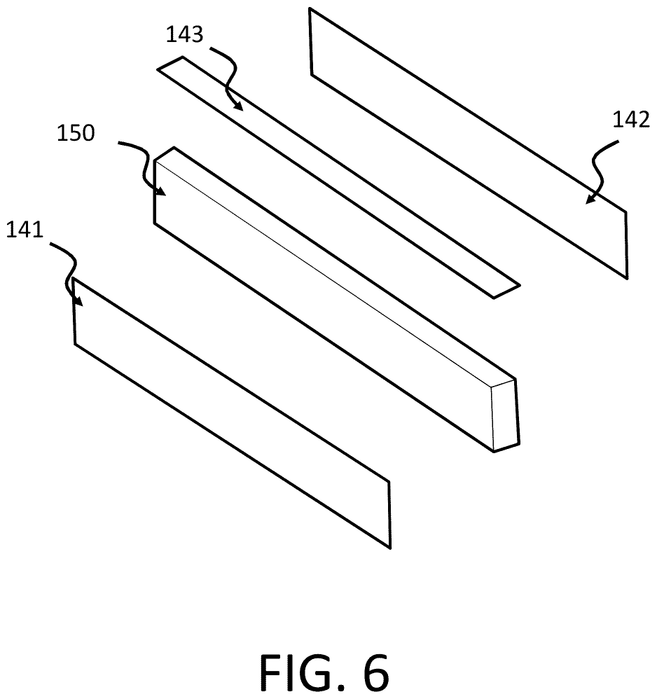

The proposed design separates drive and sense direction into X and Z axes, respectively. To obtain the correct behavior of the simulated model, two reference frames were created. Specimen frame (S_{xyz}) refers to the stationary coordinate system of the half-fork silicon base, while crystallographic (C_{abc}) frame shows the orientation of the AlN films. To observe separate drive and sense directions, drive crystallographic reference frames are rotated with respect to the specimen reference plane. The additional rotating systems were created to model the mentioned layers' orientation in COMSOL, while Euler angles configured axes switching. The overall breakdown of the piezoelectric layers' orientations is illustrated in FIG. 6.

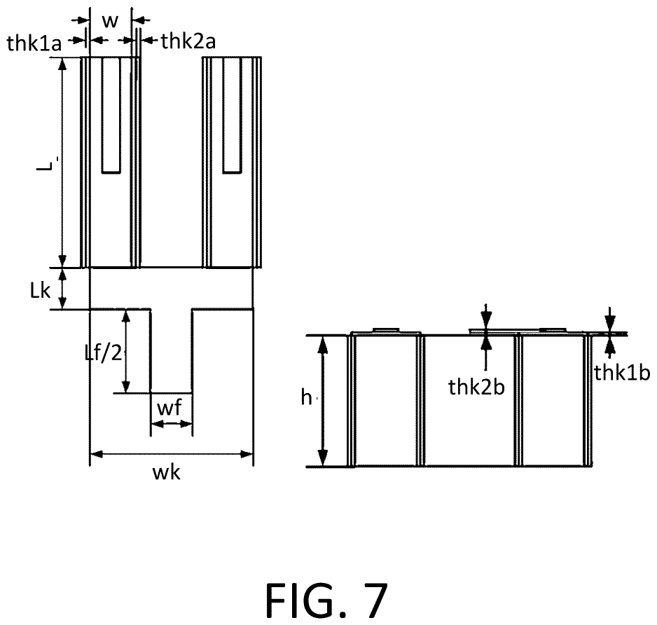

Initial dimensions of the proposed design are shown in FIG. 7, while all geometry parameters are listed in the table below.

Example values of design parameters.

| Parameter name | Value [μm] | Description |
|---|---|---|
| h | 50 | Height of the cantilever |
| w | 20 | Width of the cantilever |
| L | 400 | Length of the cantilever |
| thk1a, thk1b | 0.300 | Thickness of AlN |
| thk2a, thk2b | 0.3 | Thickness of Al contacts |
| wf | 35 | Width of the fixed end |
| Lf | 100 | Length between the fixed end |
| | | and the fork base |
| Lk | 25 | Length of the fork base |
| wk | 160 | Width of the fork base |

The eigenvalue solver from COMSOL Multiphysics uses the relation between complex eigenvalue and frequency to determine the mode shapes and value of natural resonant frequencies of the modeled gyroscope. The frequencies of interest are the drive mode (in-plane, X-axis) and the sense mode (out-of-the-plane, Z-axis).

The proposed design operates in a counter-phase to provide more accurate output with reduced quadrature error. Counter-phase mode was selected owing to its opportunity to efficiently utilize the differential output, which requires to have only two sense electrodes. In this case, the gyroscope's sensitivity constitutes the voltage difference between two cantilevers, because generated potentials have opposite signs.

While in in-phase mode sense voltage signs on each cantilever are equal, leading to the need for additional neutral electrodes and increased losses. In this example, the operational frequencies are 149.05 kHz and 256.74 kHz for drive and sense modes, respectively.

In this work, the drive mode of the proposed MEMS gyroscope is actuated by the converse piezoelectric effect. Both cantilevers of the resonator have AlN deposited thin film sidewalls with the Al electrodes on them. To increase drive displacement amplitude, AC voltage has a 180 phase difference on the sidewalls of the Al electrodes, while both cantilevers have mirrored orientation between each other to perform drive antiphase deflections.

In practice, the drive input voltage amplitude is proportional to displacement amplitude. As a result, a higher source voltage results in a higher angular rate sensitivity. However, the maximum voltage amplitude is limited due to size and practical limitations. The majority of the commercial MEMS gyroscopes have input voltage amplitude between 10 and 30 V. Moreover, some devices contain charge pumps to increase the listed values. The AC amplitude of 10 V was selected for the proposed CVG half-fork gyroscope to follow considered limitations. Initially, the damping boundary condition is presented as a loss factor damping and could be set up as a single ratio. However, this option does not consider the difference in behavior between different resonant modes. Thus, Rayleigh damping was selected for further modeling to enhance the simulation results. It is expressed as a linear combination of the mass and stiffness matrices and could be analytically calculated as follows:

$$C = {α}_{d M} M + {β}_{d K} K$$

In the above equation, parameter C is defined as a fraction of the mass and the stiffness using two parameters, α_{dM} and β_{dK}. The values of these constants can be derived from the values of drive frequency and quality factor Q_{d}.

MEMS gyroscopes require a high vacuum environment to improve their performance as with the other sensors such as accelerometers. These conditions are strongly interrelated with the resonator's structural behavior because the vacuum level affects the mechanical quality factor. The high-quality factor in the strongly encapsulated systems allows a more significant resonating displacement at lower input voltage. Experimental measuring and testing for high-hermitized MEMS gyroscopes showed that their Q-factor value is in the range between 9840 and 34,000. In addition, in recent MEMS modeling works this parameter was assumed to be between 10,000 and 30,000. However, in analytical calculations for the high-quality sensors, Q-factor can even reach 50,000. Thus, the quality factor for the proposed simulation was estimated as 20,000.

The mechanical or angular rate sensitivity was selected as an output value to estimate the potential of the simulated design. This parameter is presented in all devices with analog output and could be expressed as a relationship between output voltage (mV) and angular velocity (dps). One can determine sensitivity value by sweeping the range of angular velocities and calculating generated voltage by 1 dps velocity change.

To obtain a sensitivity value, COMSOL frequency-domain study was undertaken. With the fixed drive resonance frequency, the gyroscope was swept around different angular velocity values from −64 dps to 64 dps with a step of 8 dps.

The simulated Coriolis force amplitude was analyzed for three different cases (positive, negative, and 0 rotating frames applied) to validate the correct behavior of the antiphase out-of-the-plane oscillations.

The correlation between the applied rotating frame and sense voltage was tested using FEM in COMSOL through the frequency-domain study. Linear behavior of the received dependence allows evaluating mechanical rate sensitivity as a curve slope. Thus, the sensitivity value of the proposed gyroscope design constituted 0.013 mV/dps.

Overall, these results indicate that the achieved sensitivity value is already located in the lower border of the commercial range of MEMS gyroscopes. Moreover, the current design has a significant advantage in the case of geometrical scaling. The surface area parameter (multiplication of the device's length and width) was selected to obtain the quantitative scaling value. This characteristic contains not only crucial dimensions of the sensor but also can serve as a scaling parameter for the comparison of different MEMS devices.

The optimization study aims to investigate the proposed gyroscope design with an AlN sidewall. Geometry optimization shows interrelated parameters and their contribution to the gyroscope's output. At the same time, improved sensitivity makes this design more competitive among existing gyroscopes with analog output.

To study the possible improvements of the initial design, the model was parameterized. As mentioned before, gyroscope actuation is based on the piezoelectric effect, and AlN layers are concentrated on the gyroscope's cantilevers. Therefore, the following parameters for further optimization were selected: AlN thickness, height, and width of the cantilever.

At first, following the developed methodology, it is required to obtain the resonant frequencies for each gyroscope design. Thus, the COMSOL eigenfrequency study with the parameter sweep was performed to receive eigenmodes for all geometry combinations. As discussed, this model includes fixed plane boundary conditions, which will inevitably lead to the appearance of torsional and rotating eigenmodes. To exclude undesired modes and, at the same time to ensure that the required drive in-plane mode in antiphase will appear after simulation, the desired number of eigenfrequencies in the COMSOL study properties was selected as 4.

However, even a non-significant parameter range creates several modal frequencies (64 possible designs with 4 modes for each show 256 frequencies). In this case, manual selection of the desired mode behavior is not possible.

Firstly, eigenfrequency study results and calculated participation factors were exported from COMSOL for further analysis. The desired drive modes have displacement in X-direction with the antiphase state of the cantilevers, while unwanted mode shapes contain twisting and rotation. Therefore, to exclude unnecessary mode shapes without manual sorting, built-in COMSOL participation factor and effective mass coefficients are used as filtering variables. Furthermore, we selected 64 frequencies from the initial dataset with the smallest effective modal mass in Z-direction and the highest participation factor in the X-direction for the angular rate sensitivity study.

To obtain angular rate sensitivity, it is required to plot a sense curve and calculate the gain in sense voltage per 1 dps change of angular velocity.

With the list of resonant frequencies obtained in the previous study, mechanical rate sensitivity can be calculated for each design option. Thus, the resonant frequency was added to the list of swept parameters. All 64 geometry combinations were simulated at each own resonant frequency in this study.

The simulation showed that output results are susceptible to the cantilever geometry of the modeled gyroscope. The mechanical rate sensitivity varies between 0.0125 mV/dps to 1.21 mV/dps.

Results of the performed simulation showed that the highest sensitivity values could be obtained at the lowest height and width but with the thickest AlN layer.

Further analysis was performed to validate the gyroscope's height impact on its sense output. It validated that some geometry parameters are more interrelated with the mechanical rate sensitivity than others. To observe how the values correlate with each other, the Pearson correlation coefficient (r-Pearson) was calculated. The Pearson correlation coefficient characterizes the existence of linear dependence between two values. Its value ranges from 1 to −1, where 1 means a complete linear positive relationship, −1 means a complete linear inverse relationship, and 0—no linear correlation. Analysis revealed that the highest impact on the gyroscope's output has the cantilever's height (−0.4 Pearson's value), and AlN thickness has a smaller influence on sensitivity (0.2 Pearson's value), while the least parameters do not have any relevant correlation.

Obtained geometry dependences with the optimized simulations allow to analyze the potential improvements. Our model shows a significant increase in output sensitivity from an initial 0.013-1.23 mv/dps, what already in a comparable range with commercial devices.

The main goal of the current study was to investigate the potential of the AlN sidewall structure in the state-of-the-art MEMS design. A half-tuning fork gyroscope with the vertical AlN sidewalls was modeled to study how it couples with the inertial sensors. To analyze the proposed device's input, resonance, and output properties, FEM analysis was carried out by COMSOL Multiphysics, which includes eigenfrequency study, sensitivity analysis, and optimization.

In addition, the proposed FEM model provides a straightforward approach for comparison between the simulated gyroscope with the existing devices. Results showed that implementing the AlN sidewalls into the current piezoelectric-based MEMS design has a promising perspective. The initial model of the proposed MEMS gyroscope reached 0.013 mV/dps, which is within the lower limits of commercial devices. Despite the lower sensitivity values, the current design has a significant advantage in scaling factors. Square dimensions of the designed gyroscope are lower in several orders of magnitude compared to the existing research and commercial gyroscopes. The parameter characterization with the following optimization took place to make the proposed design more competitive in the case of angular rate sensitivity. FEM multi-parameter simulation showed that the design with a lower height and thicker AlN layer could reach the sensitivity value of more than 1.2 mV/dps.

Achieved output values of the simulated gyroscope and its significant advantage in scalability provide a solid basis for the possible implementation of the piezoelectric sidewall structure beyond inertial sensor MEMS.

According to the present disclosure, there is provided a microelectromechanical system, MEMS, device, comprising
at least one cantilever 100, the at least one cantilever 100 forming part of a silicon layer comprising highly doped silicon, the at least one cantilever comprising a top surface 130, a bottom surface, a first sidewall 110 and a second sidewall 120 such that the first and second sidewalls connect the top surface to the bottom surface in a thickness direction of the silicon layer;
a first lead-free piezoelectric layer on a first sidewall 110 of the at least one cantilever 100;
a second lead-free piezoelectric layer on a second sidewall 120 of the at least one cantilever 100;
a first electrically conductive layer 111 on the first lead-free piezoelectric layer; and
a second electrically conductive layer 121 on the second lead-free piezoelectric layer.

The first and second electrically conductive layers 111, 121 may be considered as electrodes, which may be connected to external voltage sources to cause deflection of the first and second lead-free piezoelectric layers between the first electrically conductive layer 111 and highly doped silicon, and the second electrically conductive layer 112 and highly doped silicon, respectively. Conversely, a voltage generated between the first electrically conductive layer and highly doped silicon, and second electrically conductive layer and highly doped silicon caused by the deflection of the first and second piezoelectric layer may be measured.

In an embodiment, the highly doped silicon has a resistivity of less than 0.01 Ω·cm, in another embodiment the resistivity of less than 0.005 Ω·cm, and in another embodiment the resistivity of less than 0.004 Ω·cm. The resistivity is used to allow the highly doped silicon comprised in the at least one cantilever to be used as a reference electrode.

In a preferred embodiment, the lead-free piezoelectric layer comprises aluminium nitrade (AlN).

In an embodiment, the first electrically conductive layer 111 and the second electrically conductive layer 121 comprise molybdenum (Mo), aluminium (Al) and/or titanium nitride, TiN. In an embodiment, the electrically conductive layer has a resistivity between 65 μΩ·cm and 670 μΩ·cm. In an embodiment, the electrically conductive layer has a resistivity of less than 670 μΩ·cm, or less than 500 μΩ·cm, or less than 100 μΩ·cm, or less than 70 μΩ·cm.

In an embodiment, a third lead-free piezoelectric layer and a third electrically conductive layer 131 are obtained on the top surface 130 of the at least one cantilever 100. Such third electrically conductive layer 131 may act as an electrode to obtain measurement information on physical deflections perpendicular to the first and second sidewalls. Conversely, the third electrode may assist in the generation of deflections actuated by the third lead-free piezoelectric material, when a voltage is applied between the third electrically conductive layer and the highly doped silicon. Such out-of-plane deflection may generate a voltage, measurable using the contact and the highly doped silicon material acting as a reference electrode of the cantilever. Out-of-plane is to be understood as a plane perpendicular to the imaginary plane passing through the first and second sidewall, that is perpendicular to the plane consider in-plane. Such a third electrode may be used as a so-called sense electrode to quantify deflection occurring perpendicular to the drive direction, that is, the in-plane direction.

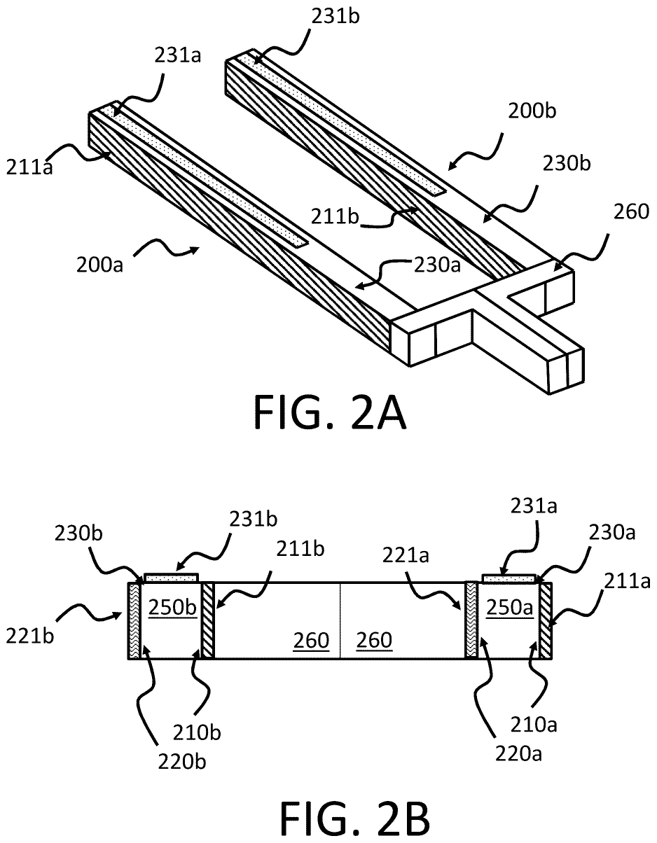

FIGS. 2A and 2B illustrate a microelectromechanical system comprising two cantilevers in accordance with at least some embodiments. The embodiment of FIGS. 2A and 2B further comprises a third electrically conductive layer 231a, 231b, which may be useful, for example, in utilizing a Coriolis vibrating gyroscope (CVG) in a microelectromechanical system (MEMS) comprising a first cantilever 200a and a second cantilever 200b parallel to the first cantilever 200a and separated by a gap. For the first cantilever 200a, a first voltage may be applied between the first electrically conductive layer 211a and the highly doped silicon 250a, and a second voltage, with opposite polarity to the first voltage, between the second electrically conductive layer 221a and the highly doped silicon 250a. For the second cantilever 200b, a third voltage may be applied between the first electrically conductive layer 210b and the highly doped silicon 250b, and a fourth voltage, with opposite polarity to the third voltage, between the second electrically conductive layer 220b and the highly doped silicon 250b. In an embodiment, that the first voltage, the second voltage, the third voltage and the fourth voltage have the same magnitude, and the first and third voltage have opposite sign with respect to the second and the fourth voltage. When the first, second, third and fourth voltages are periodically alternated, the piezoelectric layers physically deflect the first and second cantilevers periodically. This deflection occurs in the so-called drive direction, or in-plane direction. When the microelectromechanical system, MEMS, comprising cantilevers periodically vibrating in-plane, experiences rotation along an axis parallel to the first and second cantilever 200b, a deflection perpendicular to the so-called drive direction, that is out-of-plane or so-called sense direction, due to the Coriolis force. The out-of-plane deflection may be measured using the third lead-free piezoelectric layer, third electrically conductive layer 231a, 231b and the highly doped silicon 250a, 250b, as the third lead-free piezoelectric layer generates a voltage measurable between the third electrically conductive layer and highly doped silicon.

In an embodiment, the cantilever has sidewall width between 20 μm and 100 μm, such as between 20 μm and 40 μm, height between 20 μm and 100 μm, such as between 20 μm and 40 μm. The cantilever length may be between 200 μm and 1 mm, such as between 350 μm and 500 μm. Further, the piezoelectric layer may have a thickness between 500 nm and 2 μm, such as between 500 nm and 700 nm. Further, an electrically conductive layer may have a thickness between 100 nm and 500 nm, such as between 200 nm and 400 nm.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the preceding description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

### INDUSTRIAL APPLICABILITY

At least some embodiments of the present disclosure find industrial application at least in the manufacture and use of microelectromechanical systems (MEMS) and specifically electrostatic and piezoelectric MEMS transduction.

ACRONYMS LIST

| | |
|---|---|
| ALD | atomic layer deposition |
| BOX | buried oxide layer |
| C_{abc} | crystallographic frame |
| CVG | Coriolis vibrating gyroscope |
| CVD | chemical vapor deposition |
| CMOS | complementary metal-oxide semiconductor |
| dps | degrees per second, deg/s |
| FEA | finite element analysis |
| FEM | finite element method |
| HF | hydrofluoric acid |
| IoT | internet-of-things |
| MEMS | microelectromechanical system |
| MOCVD | metalorganic chemical vapor deposition |
| NEMS | nanoelectromechanical system |
| PVD | physical vapor deposition |
| PZT | lead zirconate titanate |
| RF | radiofrequency |
| SEM | scanning electron microscopy |
| S_{xyz} | specimen frame |
| Q | quality factor |
| m_{d} | material density of the built geometry in drive direction |
| mₛ | material density of the built geometry in drive direction |
| r_{d} | Rayleigh damping coefficient in drive direction |
| rₛ | Rayleigh damping coefficient in sense direction |
| k_{d} | stiffness for drive mode |
| kₛ | stiffness for sense mode |
| F_{cor} | Coriolis force |
| F_{d} | Applied force in the drive direction |
| VPE | vapor phase etching |

REFERENCE SIGNS LIST

| | |
|---|---|
| 100, 200, 300 | cantilever |
| 110, 210 | first sidewall of a cantilever |
| 120, 220 | second sidewall of a cantilever |
| 130, 230 | top surface of a cantilever |
| 111, 371 | first electrically conductive layer |
| 121, 372 | second electrically conductive layer |
| 131 | third electrically conductive layer |
| 140, 340 | lead-free piezoelectric layer |
| 141 | first lead-free piezoelectric layer |
| 142 | second lead-free piezoelectric layer |
| 143 | third lead-free piezoelectric layer |
| 150, 310 | highly doped silicon |
| 160, 260 | fixed constraint |
| 200a | first cantilever |
| 200b | second cantilever |
| 210a | first sidewall in the first cantilever |
| 210b | first sidewall in the second cantilever |
| 220a | second sidewall in the first cantilever |
| 220b | second sidewall in the second cantilever |
| 211a | first electrical layer in the first cantilever |
| 211b | first electrical layer in the second cantilever |
| 221a | second electrical layer in the first cantilever |
| 221b | second electrical layer in the second cantilever |
| 230a | top surface of the first cantilever |
| 230b | top surface of the second cantilever |
| 231a | third electrical layer in the first cantilever |
| 231b | third electrical layer in the second cantilever |
| 250a | highly doped silicon in the first cantilever |
| 250b | highly doped silicon in the second cantilever |
| 315 | insulator mask |
| 320 | buried oxide layer |
| 350 | insulator |
| 360 | device layer |
| 370 | electrically conductive layer |
| 380 | base material |
| 510 | drive direction |
| 520 | sense direction |
| 530 | proof mass |

1. A method for manufacturing a microelectromechanical system, MEMS, device, comprising:
forming at least one cantilever from a highly doped silicon layer on a buried oxide layer, the at least one cantilever having a first sidewall and a second sidewall, wherein the first and second sidewalls are perpendicular to the interface between the highly doped silicon layer and the buried oxide layer;
growing a lead-free piezoelectric layer at least on the first sidewall and the second sidewall; and
depositing electrically conductive material at least on the lead-free piezoelectric layer on the first sidewall and the second sidewall in order to form a first electrically conductive layer on the lead-free piezoelectric layer on the first sidewall and a second electrically conductive layer on the lead-free piezoelectric layer on the second sidewall.

2. The method according to claim 1, wherein the forming comprises etching at least one cavity to the highly doped silicon layer, and removing the buried oxide layer.

3. The method according to claim 1, wherein the highly doped silicon layer has a resistivity of less than 0.01 Ω·cm, or less than 0.005 Ω·cm.

4. The method according to claim 1, wherein the highly doped silicon layer is a device layer of a silicon-on-insulator, SOI, substrate.

5. The method according to claim 1, wherein the first electrically conductive layer and/or the second electrically conductive layer comprises at least one of molybdenum, Mo, titanium nitride, TiN, and aluminum, Al.

6. The method according to claim 1, wherein the buried oxide layer comprises silicon dioxide, SiO₂.

7. The method according to claim 1, wherein the lead-free piezoelectric layer comprises aluminum nitride, AlN.

8. The method according to claim 1, wherein:
the growing of the lead-free piezoelectric layer comprises growing a portion of the lead-free piezoelectric layer on a top surface of the at least one silicon beam; and
the method further comprises depositing a third electrically conductive layer on said portion of the lead-free piezoelectric layer.

9. The method according to claim 1, wherein at least two parallel silicon beams are released and separated by a gap, the gap being between 50 μm and 300 μm.

10. The method according to claim 1, wherein the at least one silicon cantilever has width between 20 μm and 100 μm, height between 20 μm and 100 μm, and length between 200 μm and 1 mm, and the lead-free piezoelectric layer has a thickness between 500 nm and 2 μm.

11. A microelectromechanical system, MEMS, device, comprising:
at least one cantilever, the at least one cantilever forming part of a silicon layer comprising highly doped silicon, the at least one cantilever comprising a top surface, a bottom surface, a first sidewall and a second sidewall such that the first and second sidewalls connect the top surface to the bottom surface in a thickness direction of the silicon layer;
a first lead-free piezoelectric layer on a first sidewall of the at least one cantilever;
a second lead-free piezoelectric layer on a second sidewall of the at least one cantilever;
a first electrically conductive layer on the first lead-free piezoelectric layer; and
a second electrically conductive layer on the second lead-free piezoelectric layer.

12. The microelectromechanical, MEMS, device according to claim 11, wherein the at least one cantilever comprises highly doped silicon with a resistivity of less than 0.01 Ω·cm, or less than 0.005 Ω·cm.

13. The microelectromechanical, MEMS, device according to claim 11, wherein the top surface is perpendicular to the first sidewall and the second sidewall.

14. The microelectromechanical, MEMS, device according to claim 11, wherein the device further comprises:
a third lead-free piezoelectric layer on the top surface of the at least one cantilever; and
a third electrically conductive layer on top of the third lead-free piezoelectric layer.

15. The microelectromechanical, MEMS, device according to claim 11, wherein at least two parallel cantilevers are separated by a gap, the gap being between 50 and 300 μm.

16. The microelectromechanical, MEMS, device according to claim 11, wherein the first and second lead-free piezoelectric layers comprise aluminum nitride, AlN.

17. The microelectromechanical, MEMS, device according to claim 11, wherein the at least one silicon cantilever has width between 20 μm and 100 μm, height between 20 μm and 100 μm, and length between 200 μm and 1 mm, and the lead-free piezoelectric layer has a thickness between 500 nm and 2 nm.

18. The microelectromechanical, MEMS, device according to claim 11, wherein the device further comprises:
a first contact electrically connected the first electrically conductive layer;
a second contact electrically connected to the second electrically conductive layer; and
a reference contact electrically connected to the highly doped silicon of the at least one cantilever.
